(19) United States
(12) Patent Application Publication
(10) Pub. No.: US 2006/0138494 A1
(43) Pub. Date: Jun. 29, 2006

(54) Photodiode in CMOS image sensor and fabricating method thereof

(76) Inventor: Chang Eun Lee, Seoul (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/319,813

(22) Filed: Dec. 27, 2005

(30) Foreign Application Priority Data
Dec. 29, 2004 (KR) 10-2004-0114602

(51) Int. Cl. H01L 31/113; H01L 21/00

(52) U.S. Cl. 257/292; 438/48; 257/E27.133

(57) ABSTRACT

A photodiode in a CMOS image sensor and fabricating method thereof are disclosed, by which the charge accumulation capacity is enhanced by enlarging a size of a photodiode area. The sensor includes a first epitaxial layer on a semiconductor substrate, a first photodiode area in the first epitaxial layer, a second epitaxial layer on the first epitaxial layer including the first photodiode area, a plug implant in the second epitaxial layer connected to the first photodiode area, and a second photodiode area in the second epitaxial layer, spaced apart from the plug implant and not to be connected to the first photodiode area.

This application claims the benefit of Korean Patent Application No. P2004-114602, filed on Dec. 29, 2004, which is hereby incorporated by reference as if fully set forth herein.

### BACKGROUND OF THE INVENTION

1. Field of the Invention

The present invention relates to a CMOS image sensor, and more particularly, to a photodiode in a CMOS image sensor and fabricating method thereof. Although the present invention is suitable for a wide scope of applications, it is particularly suitable for enhancing the charge capacity of the photodiode in a CMOS image sensor.

2. Discussion of the Related Art

Generally, an image sensor is a semiconductor device that transforms an optical image into an electric signal. Image sensors are mainly classified into a charge coupled device (hereinafter abbreviated CCD) and a complementary metal oxide semiconductor (hereinafter abbreviated CMOS) image sensor.

The CCD contains a plurality of photodiodes (PDs) arranged in a matrix form, configured to convert optical signals to electric signals; a plurality of vertical charge coupled devices (VCCD) provided between the plurality of the photodiodes to transfer charges generated from the photodiodes in the vertical direction; a horizontal charge coupled device (HCCD) to transfer a charge from each of the vertical charge coupled devices in a horizontal direction; and a sense amplifier to output the electrical signal by sensing the charge transferred in the horizontal direction.

Yet, the above-configured CCD has a complicated driving mechanism, consumes considerable power, and needs a relatively complicated fabricating process. Also, since it can be difficult to integrate a control circuit, a signal processing circuit, an analog/digital converting circuit (A/D converter) and the like on a CCD chip, the above-configured CCD may have limitations in reducing a size of product.

Recently, attention has been paid to a CMOS image sensor as a next generation image sensor that overcomes certain disadvantages of the CCD. The CMOS image sensor employs a switching method for detecting an output of each unit pixel by means of MOS transistors formed on a semiconductor substrate. The number of MOS transistors generally corresponds to unit pixels, and the CMOS technology may be used to form a control circuit, signal processing circuit and the like as peripheral circuits. Namely, the CMOS image sensor reproduces an image by detecting an electric signal from each unit pixel and transferring and/or processing that signal according to the switching method. The CMOS image sensor implements detection and transfer functions by configuring a photodiode and at least one MOS transistor within the unit pixel.

The CMOS image sensor, utilizing CMOS fabrication technology, is advantageous in low power consumption, a relatively simple fabrication process, and the like. The CMOS image sensor, which can integrate a control circuit, a signal processing circuit, an analog/digital converting circuit and the like on a CMOS sensor chip, facilitates the miniaturization of product. Hence, CMOS image sensors may contain unit pixels configured in an n-by-m matrix (where n and m are integers, the product of which may be up to several million), and CMOS image sensors are widely used for various applications such as a digital still camera, a digital video camera and the like.

CMOS image sensors may be classified into 3-T type, 4-T type, 5-T type and the like according to the number of transistors in the unit pixel. The 3-T type CMOS image sensor includes one photodiode and three transistors, and the 4-T type CMOS image sensor includes one photodiode and four transistors.

FIG. 1 is a circuit diagram of a unit pixel of a general 4-T CMOS sensor.

Referring to FIG. 1, a 4-T type CMOS image sensor consists of a photodiode PD as a photo-sensor and four NMOS transistors Tx, Rx, Dx and Sx.

A transfer transistor Tx among the four NMOS transistors plays a role in carrying photo-charges generated from the photodiode PD to a floating sensing node. A reset transistor Rx plays a role in discharging charges stored in the floating sensing node. A drive transistor Dx plays a role as a source follower, and a select transistor Sx is operative in switching and addressing (e.g., selecting the unit pixel for reading or driving).

A DC gate (not necessarily part of the unit pixel) is a load transistor allowing a predetermined current to flow to the output by applying a constant voltage as a gate potential of a transistor. ‘V_{DD}’, ‘V_{SS}’ and ‘output’ are drive power voltage, ground voltage and output voltage of a unit pixel, respectively.

In the above-explained CMOS image sensor, a configuration of the photodiode as the photo-sensor plays an important role in the charge capacity of the CMOS image sensor.

FIG. 2 is a cross-sectional diagram of a photodiode in a CMOS image sensor.

Referring to FIG. 2, reference numbers 1 to 5 indicate a semiconductor substrate, an STI (shallow trench isolation) layer for device isolation, a photodiode ion implantation diffusion layer, a depletion layer and incoming light, respectively. The depletion layer 4 is generated by applying a reverse bias to the photodiode ion implantation diffusion layer 3 (e.g., that may be used for driving the output). In the above-configured photodiode, if a reverse bias is applied to the photodiode ion implantation diffusion layer 3, the depletion layer 4 shown in FIG. 2 is formed.

Once the incoming light 5 enters the depletion layer 4, electron hole pairs (EHP) are generated. Holes are drained to the semiconductor substrate 1 and electrons are accumulated in the depletion layer 4, whereby a photodiode action is carried out. Hence, the more EHPs are generated, the better the photodiode characteristics are enhanced.

In the early stage of applying a bias to the photodiode ion implantation layer 3, the depletion layer 4 is formed wide. As the EHPs increase, electrons are accumulated within the depletion layer while holes are drained to the semiconductor substrate 1. In doing so, the depletion layer 4 is gradually reduced in accordance with incremental electron accumulation, eventually returning to a profile of the photodiode ion implantation diffusion layer 3 prior to the application of the bias.

Hence, if an area of the photodiode ion implantation injection layer 3 is small, the electron accumulation capability (i.e., charge capacity) is correspondingly reduced. If an area of the photodiode ion implantation injection layer 3 is large, charge capacity is correspondingly increased.

A method of fabricating a photodiode of a CMOS image sensor according to a related art is explained with reference to FIG. 3 as follows. FIG. 3 is a cross-sectional diagram for explaining a method of fabricating a photodiode of a CMOS image sensor according to a related art.

Referring to FIG. 3, a device isolation layer 12 for shallow trench isolation is formed in a semiconductor substrate 11. Photodiode impurity ion implantation is then carried out on the semiconductor substrate 11 to form a photodiode area 13.

In this case, the photodiode area 13 is formed by coating a photosensitive layer (not shown in the drawing) on the semiconductor substrate 11, patterning the coated photosensitive layer by exposure and development, and then implanting impurity ions into the semiconductor substrate using the patterned photosensitive layer as a mask. Subsequently, the impurity ions implanted into the photodiode area 13 are diffused by annealing.

The ions of the photodiode area 13 in the vicinity of a boundary of the STI layer 12 may diffuse into an interface between the semiconductor substrate 11 and the device isolation layer 12 in part and become bonded to ions (counter type against that of the photodiode impurities) of a field channel stop ion implantation layer under the device isolation layer 12. Hence, ion density of the photodiode area in the vicinity of the device isolation layer 12 may become smaller than that of a central part of the photodiode area 12.

As mentioned in the foregoing description, the charge capacity of the photodiode is proportional to the size of the photodiode area 13. Hence, the charge accumulation capacity of the photodiode is lowered in proportion to any decrease in the size of the photodiode area 13.

Thus, if a size of the photodiode area 13 is small, it is not a big deal in case of low illumination intensity (i.e., a relatively small quantity of the incoming light). Yet, in case of high illumination intensity (i.e., a relatively great quantity of the incoming light), if the size of photodiode area 13 decreases, it may be unable to accumulate electrons according to the conversion by the incoming light due to a reduced sensing capability of the CMOS image sensor.

### SUMMARY OF THE INVENTION

Accordingly, the present invention is directed to a photodiode in a CMOS image sensor and fabricating method thereof that substantially obviate one or more problems due to limitations and disadvantages of the related art.

An object of the present invention is to provide a photodiode in a CMOS image sensor and fabricating method thereof, by which charge accumulation capacity is enhanced by enlarging a size of a photodiode area.

Another object of the present invention is to provide a photodiode in a CMOS image sensor and fabricating method thereof, by which image sensing capability of the CMOS image sensor at high illumination intensity is enhanced.

Another object of the present invention is to provide a photodiode in a CMOS image sensor and fabricating method thereof, which enables both enhanced charge accumulation capacity and enhanced image sensing capability at high illumination intensity.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) and/or example(s) particularly pointed out in the written description and claims hereof as well as the appended drawings.

To achieve these objects and other advantages and in accordance with the purpose of the invention, as embodied and broadly described herein, a photodiode in a CMOS image sensor according to the present invention includes a first epitaxial layer on a semiconductor substrate, a first photodiode area in a predetermined surface area of the first epitaxial layer, a second epitaxial layer on the first epitaxial layer including the first photodiode area, an electrical connector in a predetermined area of the second epitaxial layer connected to the first photodiode area, and a second photodiode area in the second epitaxial layer spaced apart from the electrical connector, not connected to the first photodiode area.

In another aspect of the present invention, a method of fabricating a photodiode in a CMOS image sensor includes the steps of forming a first epitaxial layer on a semiconductor substrate, forming a first photodiode area in a predetermined surface area of the first epitaxial layer, forming a second epitaxial layer on the first epitaxial layer including the first photodiode area, forming in the second epitaxial layer (i) an electrical connector connected to the first photodiode area and (ii) a second photodiode area spaced apart from the electrical connector and not connected to the first photodiode area.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a circuit diagram of a unit pixel of a general 4-T CMOS sensor;

FIG. 2 is a cross-sectional diagram of a photodiode in a CMOS image sensor;

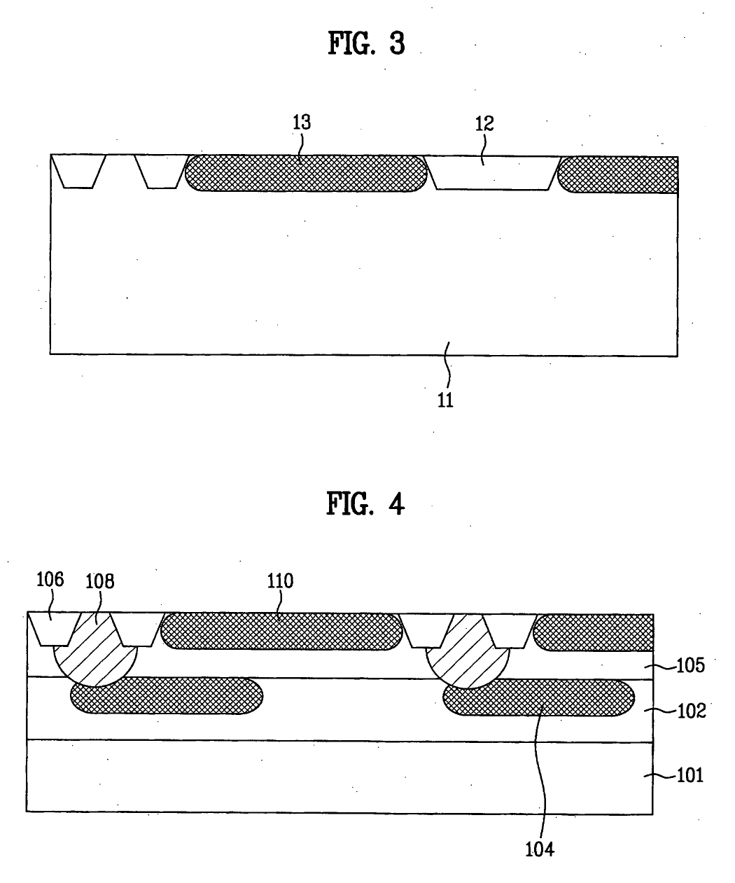

FIG. 3 is a cross-sectional diagram for explaining a method of fabricating a photodiode of a CMOS image sensor according to a related art;

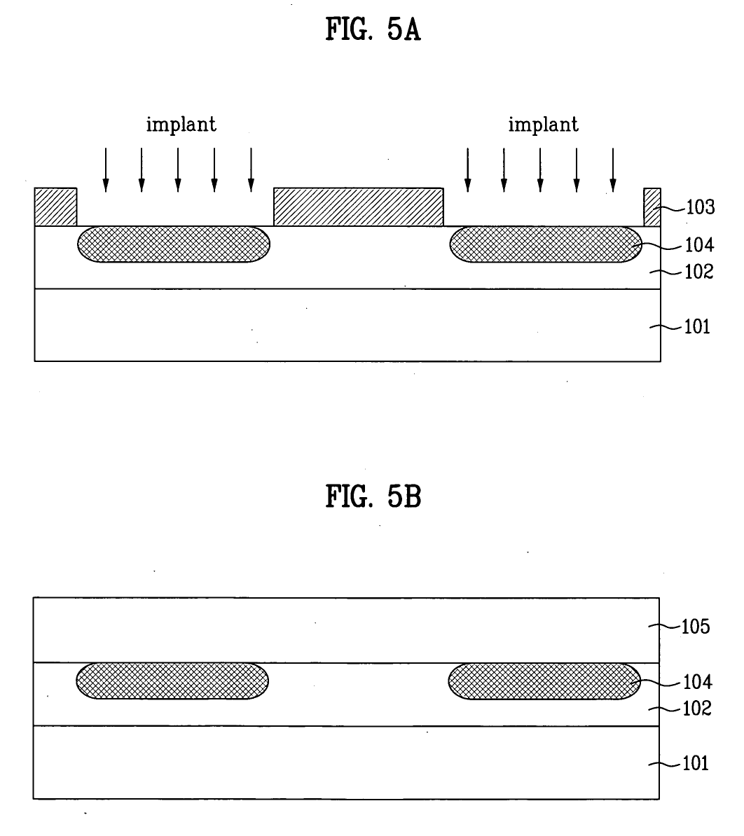

FIG. 4 is a cross-sectional diagram of a photodiode in a CMOS image sensor according to an embodiment of the present invention;

FIGS. 5A to 5D are cross-sectional diagrams for explaining a method of fabricating a photodiode in a CMOS image sensor according to an embodiment of the present invention; and

FIG. 6 is a top-down view of a photodiode in a CMOS image sensor according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

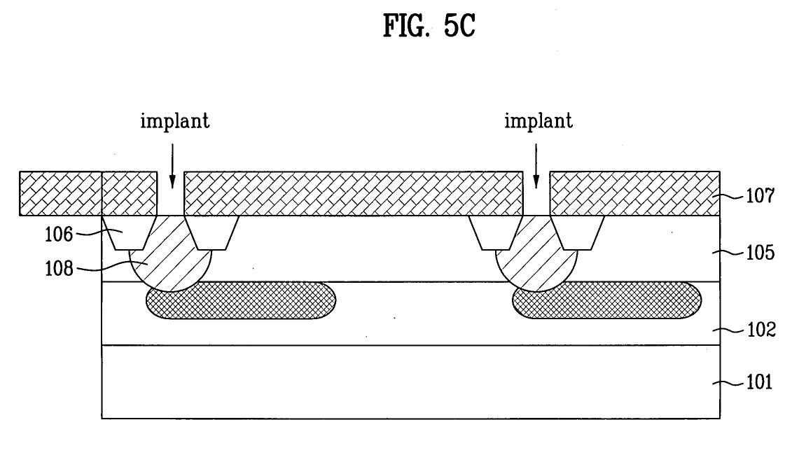

FIG. 4 is a cross-sectional diagram of a photodiode in a CMOS image sensor according to an embodiment of the present invention.

Referring to FIG. 4, a photodiode in a CMOS image sensor according to an embodiment of the present invention includes a first epitaxial layer 102 formed on a semiconductor substrate 101, a first photodiode area 104 formed in a predetermined surface area of the first epitaxial layer 102, a second epitaxial layer 105 formed on the first epitaxial layer 101 including the first photodiode area 102, an electrical contact (or connection) 108 formed in a predetermined area of the second epitaxial layer 105 and connected to the first photodiode area 104, and a second photodiode area 110 formed in the second epitaxial layer 105, spaced apart from the electrical contact 108 by a uniform interval and not connected to the first photodiode area 104. In the example of FIG. 4, electrical contact (or connection) 108 comprises an implant plug, formed by conventional ion implantation (generally between device isolation structures 106), although a conventional contact (e.g., formed by conventional tungsten plug formation and/or processing) may also be suitable.

Meanwhile, a device isolation layer 106 is formed in the second epitaxial layer 105 provided to the semiconductor substrate 101 to isolate transistors, photodiodes and/or electrical contacts/connections from each other.

In this case, the second photodiode area 110 has a greater width than the first photodiode area 104. Generally, due to its greater area, second photodiode area 110 provides relatively high sensitivity. A dynamic range, which is for distinction between light and shade, of the first diode area 104 having low sensitivity is generally greater than that of the second photodiode area 110.

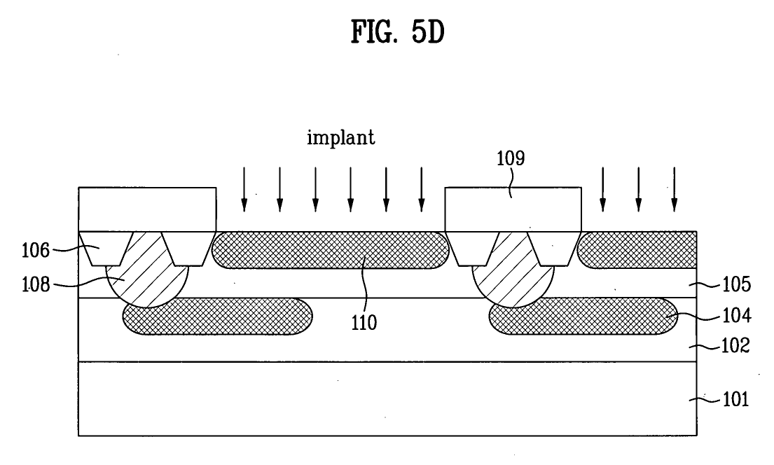

FIGS. 5A to 5D are cross-sectional diagrams for explaining a method of fabricating a photodiode in a CMOS image sensor according to an embodiment of the present invention.

Referring to FIG. 5A, a first epitaxial layer 102 is formed on a semiconductor substrate 101 by a first epitaxial deposition or growth process. Generally, the first epitaxial layer 102 comprises epitaxial silicon. In doing so, the first epitaxial layer 102 has a relatively wide and deep depletion region for a photodiode to be formed therein. This is to raise the power of a low-voltage photodiode for collecting photo-charges and to enhance photosensitivity.

After a first photoresist layer 103 has been coated on the first epitaxial layer 102, the first photoresist layer 102 is patterned by exposure and development. A first photodiode area 104 is then formed to a predetermined depth by implanting photodiode impurity ions into the first epitaxial layer 102 using the patterned first photoresist layer 103 as a mask.

Referring to FIG. 5B, after the first photoresist layer has been removed, a second epitaxial layer 105 is formed on the first epitaxial layer 102 by a second epitaxial deposition or growth process. Generally, the second epitaxial layer 105 comprises epitaxial silicon. In doing so, the first photodiode layer 104 is covered with the second epitaxial layer 105.

Referring to FIG. 5C, an active area and a device isolation area are defined on the semiconductor substrate 101 and/or the second epitaxial layer 105 that is formed thereover. And, a device isolation layer or structure 106 is formed in the device isolation area by shallow trench isolation (STI) or local oxidation of silicon (LOCOS).

In particular, the device isolation layer 106 is formed in the following manner. First of all, a pad oxide layer, a pad nitride layer and a TEOS (tetraethyl orthosilicate) oxide layer are sequentially formed on a semiconductor substrate (in this case, the second epitaxial layer 105). Then, a photoresist layer is formed on the TEOS oxide layer. Subsequently, the photoresist layer is patterned by exposure and development using a mask defining an active area and a device isolation area. In doing so, the photoresist layer corresponding to the device isolation area is removed.

The pad oxide layer, portions of the TEOS oxide layer, pad nitride layer and pad oxide layer in the device isolation area are then selectively removed using the patterned photoresist layer as a mask. The semiconductor substrate corresponding to the device isolation area is then etched to a predetermined depth to form a trench using the patterned pad oxide, pad nitride and TEOS oxide layers as a mask. The photoresist layer is then removed.

A thin sacrificial or buffer oxide layer is formed in the substrate on an inner wall of the trench, generally be wet or dry thermal oxidation. An O₃-TEOS layer is formed on the substrate to fill the trench, generally at a process temperature over 1,000° C.

Subsequently, a second photoresist layer 107 is coated over the semiconductor substrate 101 having the device isolation layer 106 formed in the second epitaxial layer 105. The second photoresist layer 107 is then patterned by exposure and development.

Meanwhile, the device isolation structures 106 may be formed there are one or more predetermined gaps therebetween, preferably to configure a dual structure as described below.

An electrical contact area 108 (in this case, an implant plug 108) is formed in the second epitaxial layer 105, generally by implanting photodiode impurity ions into the second epitaxial layer 105 over the semiconductor substrate 101 using the patterned second photoresist layer 107 as a mask. In doing so, the implant plugs 108 are connected to corresponding first photodiode areas 104. Meanwhile, the implant plugs 108 are formed by ion implantation carried out in a first, relatively narrow gap between first and second device isolation structures 106.

Referring to FIG. 5D, after the patterned second photoresist layer 107 has been removed, a third photoresist layer 109 is coated over the semiconductor substrate 101. The third photoresist layer 109 is then patterned by exposure and development.

Subsequently, a second photodiode area 110 is formed by implanting photodiode impurity ions into the second epitaxial layer 105 over the semiconductor substrate 101 using the patterned third photoresist layer 109 as a mask. In doing so, the second photodiode area 110 is formed such that it has a width greater than the first photodiode area 104. Thus, the second photodiode area 110 may be formed in a second, relatively wide gap between second and third device isolation structures 106.

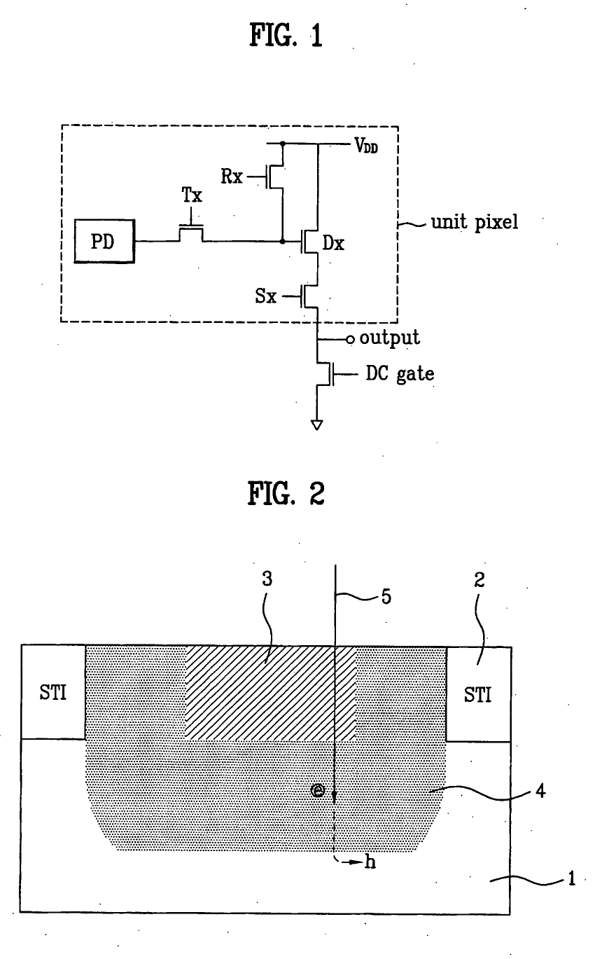

Thereafter, the patterned third photoresist layer 109 is removed, and a CMOS image sensor fabricating process is further carried out. For example, an electrical contact may be formed to each of the first and second photodiode areas 106 and 110 using conventional metallization technology, and the electrical contacts coupled to, e.g., the transmit transistor in a unit pixel such as Tx in FIG. 1.

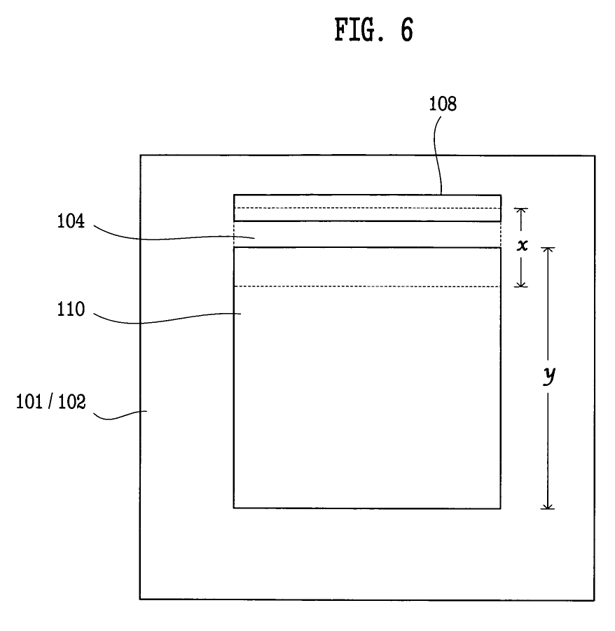

FIG. 6 shows a layout (or top-down) view of the present photosensor, such as the photosensor of FIG. 4. For sake of clarity, the device isolation structures 106 are omitted. As discussed above, the second photodiode area 110 and the implant plug 108 are spaced apart from each other in second epitaxial layer 102. Also, the second photodiode area 110 has a width y greater than the corresponding width x of the first photodiode area 106. Generally, the width ratio y:x is from 2:1 to 10:1, and a width ratio y:x of about 4:1 is preferred. Although the length of the first and second photodiode areas 106 and 110 are the same in FIG. 6, dimensions providing a second photodiode area 110-to-first photodiode area 106 area ratio of about 4:1 are generally suitable. Naturally, the present photosensor is suitable for sensing any color or color band typically employed in image sensors (e.g., red, green, blue, yellow, cyan or magenta).

Accordingly, the present invention provides the following effects or advantages.

First of all, by configuring the multi-structure (or multi-layer) photodiode area to increase the size of the photodiode area, the present invention can raise the charge capacity of the CMOS image sensor.

Therefore, it is able to fabricate the CMOS image sensor having excellent image sensing power at high illumination intensity for a great quantity of the incoming light.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A photodiode in a CMOS image sensor, comprising:
a first epitaxial layer on a semiconductor substrate;
a first photodiode area in a predetermined surface area of the first epitaxial layer;
a second epitaxial layer on the first epitaxial layer including the first photodiode area;
an electrical connector or contact in a predetermined area of the second epitaxial layer, connected to the first photodiode area; and
a second photodiode area in the second epitaxial layer, spaced apart from the plug implant, and not connected to the first photodiode area.

2. The photodiode of claim 1, wherein the second photodiode area has a width greater than that of the first photodiode area.

3. The photodiode of claim 1, wherein the second photodiode area has a surface area greater than that of the first photodiode area.

4. The photodiode of claim 2, wherein the second photodiode area and the first photodiode area have a surface area ratio of from 2:1 to 10:1.

5. The photodiode of claim 1, wherein the first photodiode area has a dynamic range greater than that of the second photodiode area.

6. The photodiode of claim 1, wherein the electrical connector or contact comprises a plug implant.

7. The photodiode of claim 1, wherein part of the second photodiode area overlies at least part of the first photodiode area.

8. The photodiode of claim 1, further comprising a plurality of device isolation structures in the second epitaxial layer, each device isolation structure being between the electrical connector or contact and an adjacent second photodiode area.

9. A method of fabricating a photodiode in a CMOS image sensor, comprising the steps of:
forming a first epitaxial layer on a semiconductor substrate;
forming a first photodiode area in a predetermined surface area of the first epitaxial layer;
forming a second epitaxial layer on the first epitaxial layer including the first photodiode area;
forming an electrical connector or contact in a predetermined area of the second epitaxial layer, connected to the first photodiode area; and
forming a second photodiode area in the second epitaxial layer, spaced apart from the electrical connector or contact and not connected to the first photodiode area.

10. The method of claim 9, further comprising the step of forming a device isolation layer in the second epitaxial layer.

11. The method of claim 10, wherein the device isolation layer comprises a plurality of device isolation structures, spaced apart by one or more predetermined gaps.

12. The method of claim 11, wherein the electrical connector or contact is formed in a first predetermined gap between first and second adjacent device isolation structures, and the second photodiode area is formed in a second predetermined gap between the second device isolation structure and a third adjacent device isolation structure.

13. The method of claim 9, wherein the electrical connector or contact comprises a plug implant.

14. The method of claim 13, wherein forming the electrical connector or contact comprises an ion implantation process.

15. The method of claim 9, wherein the second photodiode area is spaced apart from the electrical connector or contact by a uniform interval.

16. The method of claim 9, wherein forming the first photodiode area comprises a first ion implantation process.

17. The method of claim 9, wherein forming the second photodiode area comprises a second ion implantation process in an area of the second epitaxial layer over the first photodiode area.

18. The method of claim 16, wherein forming the second photodiode area comprises a second ion implantation process.
